(19) United States
(12) Patent Application Publication
(10) Pub. No.: US 2023/0007195 A1
(43) Pub. Date: Jan. 5, 2023

(54) IMAGING DEVICE AND IMAGING METHOD

(71) Applicant: Panasonic Intellectual Property Management Co., Ltd., Osaka (JP)

(72) Inventors: YASUO MIYAKE, Osaka (JP); TAKEYOSHI TOKUHARA, Osaka (JP); YOSHIAKI SATOU, Kyoto (JP); YUSUKE OKADA, Osaka (JP)

(21) Appl. No.: 17/930,598

(22) Filed: Sep. 8, 2022

Related U.S. Application Data
(63) Continuation of application No. PCT/JP2021/007185, filed on Feb. 25, 2021.

(30) Foreign Application Priority Data
Mar. 31, 2020 (JP) 2020-063063

(51) Int. Cl. H04N 5/369; H04N 5/3745; H04N 5/351

(52) U.S. Cl. CPC H04N 5/3698; H04N 5/3745; H04N 5/351; H01L 27/307

(57) ABSTRACT

An imaging device includes: a photoelectric converter whose sensitivity changes depending on a value of a voltage to be applied; and a voltage supply circuit that alternately supplies a first voltage and a second voltage, which is different from the first voltage, to the photoelectric converter, in which in a first frame period, a length of a first period from a first point in time at which the first voltage is switched to the second voltage until a second point in time at which the first voltage is switched to the second voltage subsequently to the first point in time differs from a length of a second period from the second point in time until a third point in time at which the first voltage is switched to the second voltage subsequently to the second point in time.

### BACKGROUND

### 1. Technical Field

The present disclosure relates to an imaging device and an imaging method.

### 2. Description of the Related Art

In the related art, the luminance of an image output from an imaging device has been adjusted. The luminance is adjusted in accordance with, for example, the illuminance of a subject or the like. The luminance can be adjusted by, for example, adjusting the amount of light that is incident on an imaging element. The amount of incident light can be adjusted by, for example, adjusting the diaphragm of a lens, adjusting the exposure time of a shutter, reducing light by using a neutral density (ND) filter, or the like.

The luminance can also be adjusted by, for example, adjusting the sensitivity of the imaging element. Adjustment of the sensitivity of the imaging element adjusts the amount of positive or negative charge to be read out from the imaging element. The adjustment of the amount of charge adjusts the luminance of an output image. Japanese Unexamined Patent Application Publication No. 2007-104114 and Japanese Unexamined Patent Application Publication No. 2017-135704 describe an imaging element with an adjustable sensitivity.

In the imaging element in Japanese Unexamined Patent Application Publication No. 2007-104114 and Japanese Unexamined Patent Application Publication No. 2017-135704, a voltage is applied to a photoelectric conversion layer. By controlling the time range for the voltage application, the sensitivity of the imaging element is adjusted.

### SUMMARY

If a light source blinks with a specific frequency, flicker may occur. One non-limiting and exemplary embodiment provides an imaging device that can reduce the occurrence of flicker even under such a light source.

In one general aspect, the techniques disclosed here feature an imaging device including: a photoelectric converter whose sensitivity changes depending on a value of a voltage to be applied; and a voltage supply circuit that alternately supplies a first voltage and a second voltage, which is different from the first voltage, to the photoelectric converter, in which in a first frame period, a length of a first period from a first point in time at which the first voltage is switched to the second voltage until a second point in time at which the first voltage is switched to the second voltage subsequently to the first point in time differs from a length of a second period from the second point in time until a third point in time at which the first voltage is switched to the second voltage subsequently to the second point in time.

It should be noted that general or specific embodiments may be implemented as a system, a method, an integrated circuit, a computer program, a storage medium, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

According to the imaging device and an imaging method according to aspects of the present disclosure, it is possible to obtain an image in which the occurrence of flicker is reduced even under a light source that blinks with a specific frequency.

### BRIEF DESCRIPTION OF THE DRAWINGS

FIG. 1 illustrates an exemplary circuit configuration of an imaging device according to an embodiment;

FIG. 2 schematically illustrates an exemplary device structure of a unit pixel included in the imaging device according to the embodiment;

FIG. 3A is a timing chart illustrating an example of the operation of the imaging device according to the embodiment;

FIG. 3B is an enlarged diagram of part of FIG. 3A;

FIG. 4 illustrates an example of a timing chart of control signals in a signal readout period of the imaging device according to the embodiment;

FIG. 5 is a timing chart illustrating an exposure control example using an imaging device according to a reference example;

FIG. 6 is a timing chart illustrating a first exposure control example using the imaging device according to the embodiment;

FIG. 7 is a detailed timing chart illustrating the first exposure control example using the imaging device according to the embodiment;

FIG. 8 is a detailed timing chart illustrating a second exposure control example using the imaging device according to the embodiment;

FIG. 9 is a detailed timing chart illustrating a third exposure control example using the imaging device according to the embodiment;

FIG. 10 is a detailed timing chart illustrating a fourth exposure control example using the imaging device according to the embodiment;

FIG. 11 is a detailed timing chart illustrating a fifth exposure control example using the imaging device according to the embodiment; and

FIG. 12 is a detailed timing chart illustrating a sixth exposure control example using the imaging device according to the embodiment.

### DETAILED DESCRIPTIONS

### Underlying Knowledge Forming Basis of the Present Disclosure

As a technique for adjusting the sensitivity of an imaging element, a technique of applying a pulsed voltage to a photoelectric conversion layer and controlling a duty ratio thereof has been known. However, it has turned out that if such a sensitivity control technique is used, flicker occurs in an image captured in a situation where a light source blinks with a specific frequency. For such an issue, the inventors have arrived at the present disclosure by focusing on a cycle of a bias voltage to be applied to the photoelectric conversion layer.

### Outline of Aspects of the Present Disclosure

An imaging device according to a first aspect of the present disclosure includes: a photoelectric converter whose sensitivity changes depending on a value of a voltage to be applied; and a voltage supply circuit that supplies a first voltage and a second voltage, which is different from the first voltage, in which the voltage supply circuit alternately supplies the first voltage and the second voltage to the photoelectric converter in a first frame period so as to form a first low-sensitivity exposure period, a first high-sensitivity exposure period, a second low-sensitivity exposure period, and a second high-sensitivity exposure period successively in this order, and the total length of the first low-sensitivity exposure period and the first high-sensitivity exposure period differs from the total length of the second low-sensitivity exposure period and the second high-sensitivity exposure period.

Thus, since the total length of the successive low-sensitivity exposure period and high-sensitivity exposure period, that is, an exposure cycle, varies in one frame period, it is possible to obtain an image in which the occurrence of flicker is reduced even under a light source that blinks with a specific frequency.

An imaging device according to a second aspect of the present disclosure includes: a photoelectric converter whose sensitivity changes depending on a value of a voltage to be applied; and a voltage supply circuit that supplies a first voltage and a second voltage, which is different from the first voltage, in which the voltage supply circuit alternately supplies the first voltage and the second voltage to the photoelectric converter in a first frame period so as to form a first low-sensitivity exposure period and a first high-sensitivity exposure period successively in this order, and alternately supplies the first voltage and the second voltage to the photoelectric converter in a second frame period, which is different from the first frame period, so as to form a second low-sensitivity exposure period and a second high-sensitivity exposure period successively in this order, and the total length of the first low-sensitivity exposure period and the first high-sensitivity exposure period differs from the total length of the second low-sensitivity exposure period and the second high-sensitivity exposure period.

Thus, since the total length of the successive low-sensitivity exposure period and high-sensitivity exposure period, that is, the exposure cycle, varies in different frame periods, it is possible to obtain an image in which the occurrence of flicker is reduced even under a light source that blinks with a specific frequency.

In an imaging device according to a third aspect of the present disclosure, the length of the first low-sensitivity exposure period differs from the length of the second low-sensitivity exposure period. Thus, the exposure cycle varies in such a manner that the lengths of the low-sensitivity exposure periods are different.

In an imaging device according to a fourth aspect of the present disclosure, the length of the first high-sensitivity exposure period differs from the length of the second high-sensitivity exposure period. Thus, the exposure cycle varies in such a manner that the lengths of the high-sensitivity exposure periods are different.

An imaging device according to a fifth aspect of the present disclosure further includes a signal detection transistor including a gate connected to the photoelectric converter, in which the signal detection transistor outputs a signal corresponding to a potential of the gate in a period in which the first voltage is supplied to the photoelectric converter. Thus, the signal is read out in the low-sensitivity exposure period.

An imaging device according to a sixth aspect of the present disclosure further includes a signal detection transistor including a gate connected to the photoelectric converter, in which the signal detection transistor outputs a signal corresponding to a potential of the gate in a period in which the second voltage is supplied to the photoelectric converter. Thus, the signal is read out in the high-sensitivity exposure period.

In an imaging device according to a seventh aspect of the present disclosure, the photoelectric converter is one of a plurality of photoelectric converters arranged in a matrix, a plurality of signal detection transistors corresponding to the plurality of photoelectric converters sequentially output, in units of row, signals corresponding to a plurality of rows in respective periods, each of the signals being a signal corresponding to a potential of a gate of a corresponding one of the plurality of signal detection transistors, each of the periods being a period in which the first voltage is supplied to a corresponding one of the plurality of photoelectric converters, and the plurality of signal detection transistors cyclically output the signals corresponding to the plurality of rows. Thus, readout of the signals from the photoelectric converters in a fixed number of rows is repeated in a fixed cycle.

In an imaging device according to an eighth aspect of the present disclosure, the photoelectric converter includes a first electrode, a second electrode, and a photoelectric conversion layer sandwiched between the first electrode and the second electrode, and the voltage supply circuit alternately supplies the first voltage and the second voltage to the first electrode of the photoelectric converter. Thus, a stacked-type image sensor in which the photoelectric converter is formed above a signal detection circuit is formed, enabling downsizing of the imaging device.

An imaging method according to a first aspect of the present disclosure is an imaging method using a photoelectric converter whose sensitivity changes depending on a value of a voltage to be applied, in which a first voltage and a second voltage, which is different from the first voltage, are alternately supplied to the photoelectric converter in a first frame period so as to form a first low-sensitivity exposure period, a first high-sensitivity exposure period, a second low-sensitivity exposure period, and a second high-sensitivity exposure period successively in this order, and the total length of the first low-sensitivity exposure period and the first high-sensitivity exposure period differs from the total length of the second low-sensitivity exposure period and the second high-sensitivity exposure period.

Thus, since the total length of the successive low-sensitivity exposure period and high-sensitivity exposure period, that is, the exposure cycle, varies in one frame period, it is possible to obtain an image in which the occurrence of flicker is reduced even under a light source that blinks with a specific frequency.

An imaging method according to a second aspect of the present disclosure is an imaging method using a photoelectric converter whose sensitivity changes depending on a value of a voltage to be applied, in which a first voltage and a second voltage, which is different from the first voltage, are alternately supplied to the photoelectric converter in a first frame period so as to form a first low-sensitivity exposure period and a first high-sensitivity exposure period successively in this order, the first voltage and the second voltage are alternately supplied to the photoelectric converter in a second frame period, which is different from the first frame period, so as to form a second low-sensitivity exposure period and a second high-sensitivity exposure period successively in this order, and the total length of the first low-sensitivity exposure period and the first high-sensitivity exposure period differs from the total length of the second low-sensitivity exposure period and the second high-sensitivity exposure period.

Thus, since the total length of the successive low-sensitivity exposure period and high-sensitivity exposure period, that is, the exposure cycle, varies in different frame periods, it is possible to obtain an image in which the occurrence of flicker is reduced even under a light source that blinks with a specific frequency.

Now, an embodiment of the present disclosure will be described in detail with reference to the drawings. Note that the embodiment described below illustrates general or specific examples. Any numeric value, shape, material, structural element, arrangement and connection of structural elements, step, order of steps, and the like illustrated in the following embodiment are examples and do not intend to limit the present disclosure. Various aspects described herein can be combined with each other without inconsistency. In the following description, structural elements having substantially the same function are denoted by the same reference numeral and may not be repeatedly described.

The term “high-sensitivity exposure period” and the term “low-sensitivity exposure period” are used herein. The high-sensitivity exposure period indicates a period in which a higher sensitivity is obtained than in the low-sensitivity exposure period. The low-sensitivity exposure period indicates a period in which a lower sensitivity is obtained than in the high-sensitivity exposure period. The sensitivity being low herein is a concept including the sensitivity being zero. The low-sensitivity exposure period is a concept including a period in which the sensitivity is zero.

Ordinals such as first, second, and third may be used herein. An element with an ordinal does not necessarily require the presence of an element of the same kind with a smaller ordinal.

### EMBODIMENT

### Circuit Configuration of Imaging Device

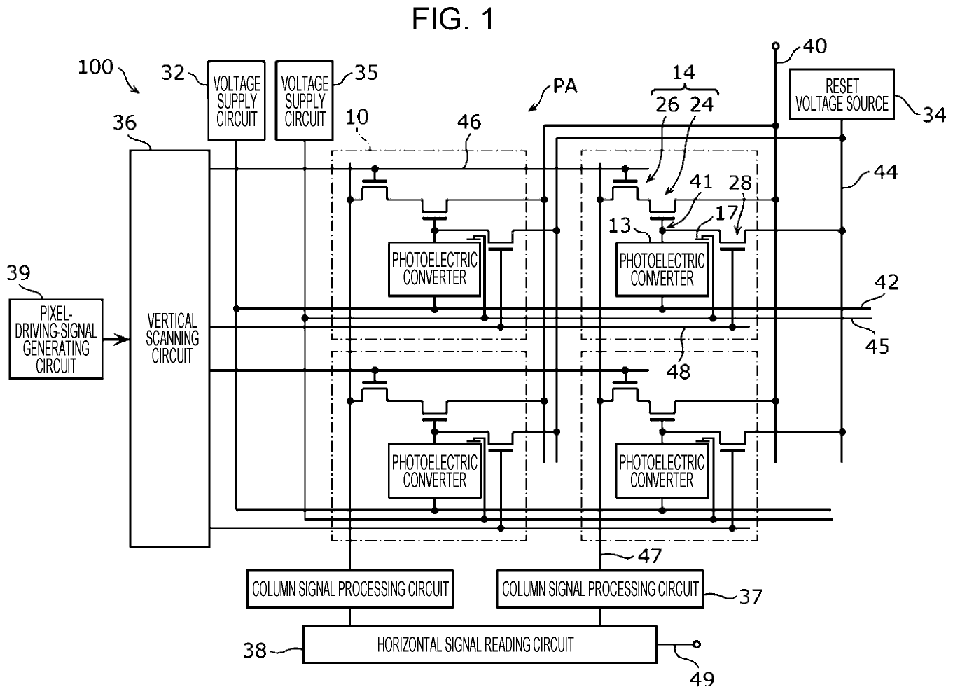

FIG. 1 illustrates an exemplary circuit configuration of an imaging device 100 according to the embodiment. The imaging device 100 illustrated in FIG. 1 includes a pixel array PA including a plurality of unit pixels 10 that are arrayed two-dimensionally. FIG. 1 schematically illustrates an example in which the unit pixels 10 are arranged in a matrix of two rows and two columns. It is needless to say that the number and arrangement of the unit pixels 10 in the imaging device 100 are not limited to those in the example illustrated in FIG. 1.

Each of the unit pixels 10 includes a photoelectric converter 13 and a signal detection circuit 14. As will be described later with reference to a drawing, the photoelectric converter 13 includes a photoelectric conversion layer sandwiched between two electrodes facing each other and generates a signal by receiving incident light. The entirety of the photoelectric converter 13 does not need to be an element that is independent for each of the unit pixels 10, and, for example, part of the photoelectric converter 13 may be formed across the plurality of unit pixels 10. The signal detection circuit 14 is a circuit that detects the signal generated by the photoelectric converter 13. In this example, the signal detection circuit 14 includes a signal detection transistor 24 and an address transistor 26. Each of the signal detection transistor 24 and the address transistor 26 is typically a field-effect transistor (FET) and is an N-channel metal oxide semiconductor (MOS) transistor in this example.

As schematically illustrated in FIG. 1, a control terminal (gate in this example) of the signal detection transistor 24 has an electrical connection with the photoelectric converter 13. Signal charge (holes or electrons) generated by the photoelectric converter 13 is accumulated in a charge accumulation section 41. The charge accumulation section 41 spreads in a region including a region between the gate of the signal detection transistor 24 and the photoelectric converter 13. The charge accumulation section 41 includes so-called floating diffusion. Details of the structure of the photoelectric converter 13 will be described later.

The imaging device 100 includes a driving section that drives the pixel array PA and acquires images at a plurality of timings. The driving section includes a voltage supply circuit 32, a voltage supply circuit 35, a reset voltage source 34, a vertical scanning circuit 36, column signal processing circuits 37, a horizontal signal reading circuit 38, and a pixel-driving-signal generating circuit 39.

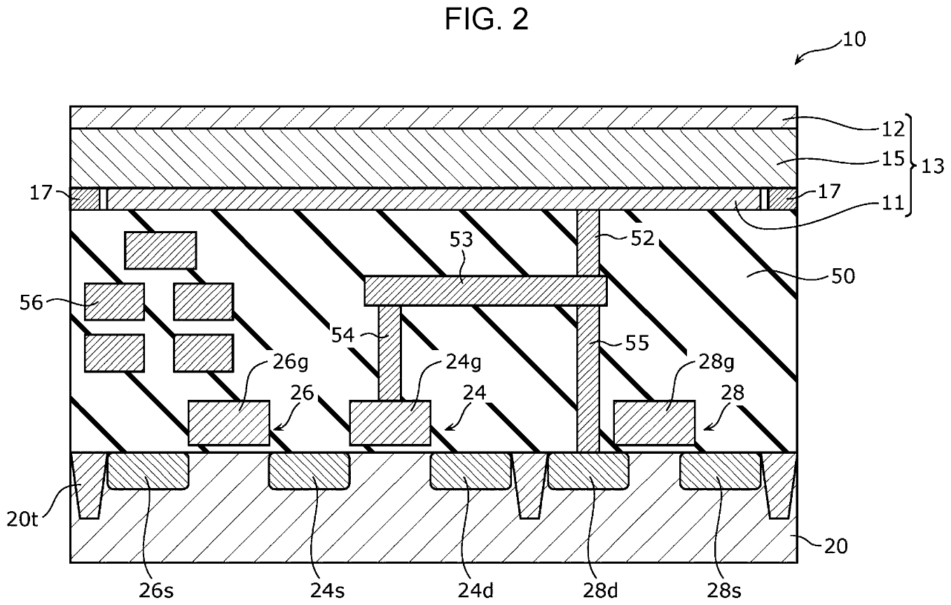

The photoelectric converter 13 in each of the unit pixels 10 further has a connection with a sensitivity control line 42. In the configuration illustrated in FIG. 1, the sensitivity control line 42 is connected to the voltage supply circuit 32. As will be described later in detail, the voltage supply circuit 32 supplies a voltage to a counter electrode 12 (see FIG. 2), the voltage being different in a high-sensitivity exposure period and in a low-sensitivity exposure period. The voltage supplied to the counter electrode 12 (see FIG. 2) may differ in different frames.

As will be described later with reference to FIG. 2, the photoelectric converter 13 includes a pixel electrode 11 and a photoelectric conversion layer 15 in addition to the counter electrode 12. In addition, in the configuration illustrated in FIG. 1, a shield electrode 17 has a connection with a sensitivity control line 45. The sensitivity control line 45 is connected to the voltage supply circuit 35. The voltage supply circuit 35 supplies a shield voltage to the shield electrode 17. Typically, the shield electrode 17 and the pixel electrode 11 are electrically isolated from each other. In the example in FIGS. 1 and 2, the shield electrode 17 and the pixel electrode 11 are separated from each other. In this example, the shield electrode 17 and the pixel electrode 11 are in contact with a surface of the photoelectric conversion layer 15, and the counter electrode 12 is in contact with the other surface of the photoelectric conversion layer 15.

The shield voltage in the shield electrode 17 may be used to suppress crosstalk between the unit pixels 10. For example, crosstalk may be suppressed by applying the shield voltage to the shield electrode 17, the shield voltage being lower than a reset voltage Vr applied to the pixel electrode 11. The shield voltage applied to the shield electrode 17 may be a negative voltage.

When viewed in the thickness direction of the pixel electrode 11, that is, in a plan view, the shield electrode 17 may surround the pixel electrode 11. More specifically, a plurality of through-holes may be provided in the shield electrode 17, and each of pixel electrodes 11 may be provided in a corresponding one of the through-holes. The shield electrode 17 may be a single electrode or may be constituted by a plurality of electrodes that are separated from one another.

Note that the sensitivity control line 45 and the voltage supply circuit 35 may be omitted, and the shield electrode 17 may be connected to ground of the imaging device 100. Crosstalk may also be suppressed in this manner. In addition, the shield electrode 17, the sensitivity control line 45, and the voltage supply circuit 35 may be omitted.

In “high-sensitivity exposure period”, either positive charge or negative charge (signal charge) generated through photoelectric conversion is accumulated in the charge accumulation section 41 with a relatively high sensitivity. That is, in “high-sensitivity exposure period”, light is converted into an electric signal with a relatively high sensitivity. In addition, in “low-sensitivity exposure period”, either positive charge or negative charge (signal charge) generated through photoelectric conversion is accumulated in the charge accumulation section 41 with a relatively low sensitivity. That is, in “low-sensitivity exposure period”, light is converted into an electric signal with a relatively low sensitivity. The sensitivity being low includes the sensitivity being zero.

By controlling the potential of the counter electrode 12 with respect to the potential of the pixel electrode 11, it is possible to collect, in the pixel electrode 11, either holes or electrons from hole-electron pairs generated in the photoelectric conversion layer 15 through photoelectric conversion (see FIG. 2). For example, in a case of using holes as signal charge, it is possible to selectively collect holes in the pixel electrode 11 by making the potential of the counter electrode 12 higher than that of the pixel electrode 11. The amount of signal charge collected per unit time varies depending on the potential difference between the pixel electrode 11 and the counter electrode 12. A case of using holes as signal charge will be described below. As a matter of course, electrons may also be used as signal charge. Each of the voltage supply circuit 32 and the voltage supply circuit 35 is not limited to a specific power source circuit and may be a circuit that generates a predetermined voltage or a circuit that converts a voltage supplied from another power source to a predetermined voltage.

Each of the unit pixels 10 has a connection with a power source line 40 that supplies a power source voltage VDD. As illustrated, an input terminal (typically, drain) of the signal detection transistor 24 is connected to the power source line 40. By the power source line 40 serving as a source follower power source, the signal detection transistor 24 amplifies and outputs a signal generated by the photoelectric converter 13.

An input terminal (drain in this example) of the address transistor 26 is connected to an output terminal (source in this example) of the signal detection transistor 24. An output terminal (source in this example) of the address transistor 26 is connected to one of a plurality of vertical signal lines 47 arranged for the respective columns of the pixel array PA. A control terminal (gate in this example) of the address transistor 26 is connected to an address control line 46, and by controlling the potential of the address control line 46, an output of the signal detection transistor 24 can be selectively read out to the corresponding vertical signal line 47.

In the illustrated example, the address control line 46 is connected to the vertical scanning circuit 36. The vertical scanning circuit 36 is also referred to as “row scanning circuit”. By applying a predetermined voltage to the address control line 46, the vertical scanning circuit 36 selects, in units of row, the plurality of unit pixels 10 arranged in each row. Thus, signal readout and reset are performed on the selected unit pixels 10.

Furthermore, the pixel-driving-signal generating circuit 39 is connected to the vertical scanning circuit 36. In the illustrated example, the pixel-driving-signal generating circuit 39 generates signals for driving the unit pixels 10 arranged in the respective rows of the pixel array PA. The generated pixel driving signals are supplied to unit pixels 10 in a row selected by the vertical scanning circuit 36.

The vertical signal lines 47 are main signal lines for transmitting pixel signals from the pixel array PA to peripheral circuits. The column signal processing circuits (also referred to as “row signal accumulating circuits”) 37 are connected to the vertical signal lines 47. The column signal processing circuits 37 perform noise suppressing signal processing, analog-to-digital conversion (AD conversion), and the like. The noise suppressing signal processing is typified by correlated double sampling. As illustrated, the column signal processing circuits 37 are provided to correspond to the respective columns of the unit pixels 10 in the pixel array PA. The horizontal signal reading circuit 38 is connected to these column signal processing circuits 37. The horizontal signal reading circuit 38 is also referred to as “column scanning circuit”. The horizontal signal reading circuit 38 sequentially reads out signals from the plurality of column signal processing circuits 37 and outputs them to a horizontal common signal line 49.

In the configuration illustrated in FIG. 1, each of the unit pixels 10 includes a reset transistor 28. Similarly to the signal detection transistor 24 and the address transistor 26, the reset transistor 28 may be, for example, a field-effect transistor. The following description illustrates an example of applying an N-channel MOS transistor to the reset transistor 28 unless otherwise specified. As illustrated, the reset transistor 28 is connected between a reset voltage line 44 for supplying a reset voltage Vr and the charge accumulation section 41. A control terminal (gate in this example) of the reset transistor 28 is connected to a reset control line 48, and by controlling the potential of the reset control line 48, the potential of the charge accumulation section 41 can be reset to the reset voltage Vr. In this example, the reset control line 48 is connected to the vertical scanning circuit 36. Thus, by the vertical scanning circuit 36 applying a predetermined voltage to the reset control line 48, the plurality of unit pixels 10 arranged in the respective rows can be reset in units of row.

In this example, the reset voltage line 44 for supplying the reset voltage Vr to the reset transistor 28 is connected to the reset voltage source 34. The reset voltage source 34 may have any configuration that can supply the predetermined reset voltage Vr to the reset voltage line 44 in the operation of the imaging device 100, and is not limited to a specific power source circuit similarly to the voltage supply circuit 32 described above. Each of the voltage supply circuit 32, the voltage supply circuit 35, and the reset voltage source 34 may be part of a single voltage supply circuit or independent, separate voltage supply circuits. Note that at least one of the voltage supply circuit 32, the voltage supply circuit 35, or the reset voltage source 34 may be part of the vertical scanning circuit 36. Alternatively, a sensitivity control voltage from the voltage supply circuit 32, a sensitivity control voltage from the voltage supply circuit 35, and/or the reset voltage Vr from the reset voltage source 34 may be supplied to the unit pixels 10 through the vertical scanning circuit 36.

It is also possible to use the power source voltage VDD of the signal detection circuit 14 as the reset voltage Vr. In this case, a voltage supply circuit (not illustrated in FIG. 1) that supplies the power source voltage VDD to the unit pixels 10 and the reset voltage source 34 may be shared. In addition, since the power source line 40 and the reset voltage line 44 may be shared, wiring in the pixel array PA may be simplified. Note that the reset voltage Vr being a voltage different from the power source voltage VDD of the signal detection circuit 14 enables more flexible control of the imaging device 100.

### Device Structure of Unit Pixel

FIG. 2 schematically illustrates an exemplary device structure of each of the unit pixels 10 included in the imaging device 100 according to the embodiment. In the structure illustrated in FIG. 2, the signal detection transistor 24, the address transistor 26, and the reset transistor 28 are formed on a semiconductor substrate 20. The semiconductor substrate 20 is not limited to a substrate the entirety of which is a semiconductor. The semiconductor substrate 20 may also be an insulating substrate having a surface on which a semiconductor layer is formed and on which a photosensitive region is to be formed. In this example, a P-type silicon (Si) substrate is used as the semiconductor substrate 20.

The semiconductor substrate 20 includes impurity regions (N-type regions in this example) 26s, 24s, 24d, 28d, and 28s and an element isolation region 20t for electric isolation between the unit pixels 10. In this example, the element isolation region 20t is also provided between the impurity region 24d and the impurity region 28d. The element isolation region 20t is formed by, for example, implantation of acceptor ions under predetermined implantation conditions.

The impurity regions 26s, 24s, 24d, 28d, and 28s are typically diffusion layers formed in the semiconductor substrate 20. As schematically illustrated in FIG. 2, the signal detection transistor 24 includes the impurity region 24s, the impurity region 24d, and a gate electrode 24g (typically, a polysilicon electrode). The impurity region 24s serves as, for example, a source region of the signal detection transistor 24. The impurity region 24d serves as, for example, a drain region of the signal detection transistor 24. A channel region of the signal detection transistor 24 is formed between the impurity region 24s and the impurity region 24d.

Similarly, the address transistor 26 includes the impurity region 26s, the impurity region 24s, and a gate electrode 26g (typically, a polysilicon electrode) connected to the address control line 46 (see FIG. 1). In this example, the signal detection transistor 24 and the address transistor 26 are electrically connected to each other by sharing the impurity region 24s. The impurity region 26s serves as, for example, a source region of the address transistor 26. The impurity region 26s has a connection with the vertical signal line 47 (see FIG. 1) that is not illustrated in FIG. 2. The reset transistor 28 includes the impurity region 28d, the impurity region 28s, and a gate electrode 28g (typically, a polysilicon electrode) connected to the reset control line 48 (see FIG. 1). The impurity region 28s serves as, for example, a source region of the reset transistor 28. The impurity region 28s has a connection to the reset voltage line 44 (see FIG. 1) that is not illustrated in FIG. 2.

On the semiconductor substrate 20, an interlayer insulating layer 50 (typically, a silicon dioxide layer) is disposed to cover the signal detection transistor 24, the address transistor 26, and the reset transistor 28. As illustrated, wiring layers 56 may be disposed in the interlayer insulating layer 50. The wiring layers 56 are typically formed of a metal such as copper, and, for example, may partly include wiring such as the vertical signal line 47 described above. The number of insulating layers in the interlayer insulating layer 50 and the number of the wiring layers 56 disposed in the interlayer insulating layer 50 may be set to any numbers and are not limited to the numbers in the example illustrated in FIG. 2.

On the interlayer insulating layer 50, the photoelectric converter 13 described above is disposed. In other words, in the embodiment of the present disclosure, the plurality of unit pixels 10 constituting the pixel array PA (see FIG. 1) are formed on the semiconductor substrate 20. The plurality of unit pixels 10 that are arrayed two-dimensionally on the semiconductor substrate 20 form a photosensitive region (pixel region). The distance between two adjacent unit pixels 10 (pixel pitch) may be, for example, about 2 μm. In the above manner, the imaging device 100 according to the embodiment is a stacked-type image sensor in which the photoelectric converter 13 is disposed above the signal detection circuit 14 formed on the semiconductor substrate 20.

The photoelectric converter 13 includes the pixel electrode 11, which is an example of a second electrode, the counter electrode 12, which is an example of a first electrode, and the photoelectric conversion layer 15, which is disposed therebetween. In this example, the counter electrode 12 and the photoelectric conversion layer 15 are formed across the plurality of unit pixels 10. On the other hand, the pixel electrode 11 is provided for each of the unit pixels 10 and is spatially isolated from the pixel electrode 11 of another adjacent unit pixel 10 to be electrically isolated from the pixel electrode 11 of the other unit pixel 10.

The counter electrode 12 is typically a transparent electrode formed of a transparent conductive material. The counter electrode 12 is disposed on a surface of the photoelectric conversion layer 15 on which light is incident. Thus, light passing though the counter electrode 12 is incident on the photoelectric conversion layer 15. Note that the light detected by the imaging device 100 is not limited to light within the wavelength range of visible light. The wavelength range of visible light is, for example, greater than or equal to 380 nm and less than or equal to 780 nm. The term “transparent” herein means that at least part of light in a wavelength range to be detected passes, and light in the entire wavelength range of visible light does not necessarily pass. Note that general electromagnetic waves including infrared rays and ultraviolet rays are expressed as “light” herein for convenience. For the counter electrode 12, for example, it is possible to use a transparent conducting oxide (TCO) such as ITO, IZO, AZO, FTO, SnO₂, TiO₂, or ZnO₂.

The photoelectric conversion layer 15 receives incident light and generates hole-electron pairs. The photoelectric conversion layer 15 is typically formed of an organic semiconductor material. Specific examples of the materials for forming the photoelectric conversion layer 15 will be described later. The photoelectric conversion layer 15 typically has a film-like shape.

As described with reference to FIG. 1, the counter electrode 12 has a connection with the sensitivity control line 42 connected to the voltage supply circuit 32. The counter electrode 12 may be formed across the plurality of unit pixels 10. In this manner, it is possible to apply a sensitivity control voltage with a desired value across the plurality of unit pixels 10 at once from the voltage supply circuit 32 through the sensitivity control line 42. It is also possible to form the counter electrode 12 so as to apply the sensitivity control voltage according to the row in the pixel array PA at once. As long as the sensitivity control voltage with a desired value can be applied from the voltage supply circuit 32, the counter electrode 12 may be provided to be isolated for each of the unit pixels 10. Similarly, the photoelectric conversion layer 15 may be provided to be isolated for each of the unit pixels 10.

By controlling the potential of the counter electrode 12 with respect to the potential of the pixel electrode 11, it is possible to collect, in the pixel electrode 11, either holes or electrons from hole-electron pairs generated through photoelectric conversion in the photoelectric conversion layer 15. For example, in a case of using holes as signal charge, it is possible to selectively collect holes in the pixel electrode 11 by making the potential of the counter electrode 12 higher than that of the pixel electrode 11. The amount of signal charge collected per unit time varies depending on the potential difference between the pixel electrode 11 and the counter electrode 12. A case of using holes as signal charge will be described below. As a matter of course, electrons may also be used as signal charge.

By an appropriate bias voltage being applied between the counter electrode 12 and the pixel electrode 11, the pixel electrode 11 facing the counter electrode 12 collects either positive charge or negative charge generated through photoelectric conversion in the photoelectric conversion layer 15. The pixel electrode 11 is formed of a metal such as aluminum or copper, a metal nitride, a polysilicon that becomes conductive by an impurity being doped thereto, or the like.

The pixel electrode 11 may be a light-blocking electrode. For example, by forming a TaN electrode with a thickness of 100 nm as the pixel electrode 11, a sufficient light-blocking property can be obtained. By forming the pixel electrode 11 as a light-blocking electrode, light that passes through the photoelectric conversion layer 15 can be prevented from being incident on a channel region or an impurity region of a transistor formed on the semiconductor substrate 20. The transistor in this example is, for example, at least any of the signal detection transistor 24, the address transistor 26, or the reset transistor 28. A light-blocking film may be formed in the interlayer insulating layer 50 by using the wiring layers 56 described above. Prevention of light, by using such a light-blocking electrode or light-blocking film, from being incident on a channel region of a transistor formed on the semiconductor substrate 20 may prevent shift of transistor characteristics (e.g., variations in threshold voltage), for example. In addition, prevention of light from being incident on an impurity region formed in the semiconductor substrate 20 may prevent noise generated by unintended photoelectric conversion in the impurity region from being mixed. In this manner, prevention of light from being incident on the semiconductor substrate 20 contributes to improvement of reliability of the imaging device 100.

As schematically illustrated in FIG. 2, the pixel electrode 11 is connected to the gate electrode 24g of the signal detection transistor 24 through a plug 52, a wiring 53, and a plug 54. In other words, the gate of the signal detection transistor 24 has an electrical connection with the pixel electrode 11. The plug 52 and the wiring 53 can be formed of, for example, a metal such as copper. The plug 52, the wiring 53, and the plug 54 form at least part of the charge accumulation section 41 (see FIG. 1) between the signal detection transistor 24 and the photoelectric converter 13. The wiring 53 may be part of the wiring layers 56. In addition, the pixel electrode 11 is also connected to the impurity region 28d via the plug 52, the wiring 53, and a plug 55. In the structure illustrated in FIG. 2, the gate electrode 24g of the signal detection transistor 24, the plug 52, the wiring 53, the plugs 54 and 55, and the impurity region 28d being either the source region or the drain region of the reset transistor 28 serve as the charge accumulation section 41 that accumulates signal charge collected in the pixel electrode 11.

Since the signal charge is collected in the pixel electrode 11, a voltage in accordance with the amount of the signal charge accumulated in the charge accumulation section 41 is applied to the gate of the signal detection transistor 24. The signal detection transistor 24 amplifies the voltage. The voltage amplified by the signal detection transistor 24 is selectively read out as a signal voltage through the address transistor 26.

### Operation of Imaging Device

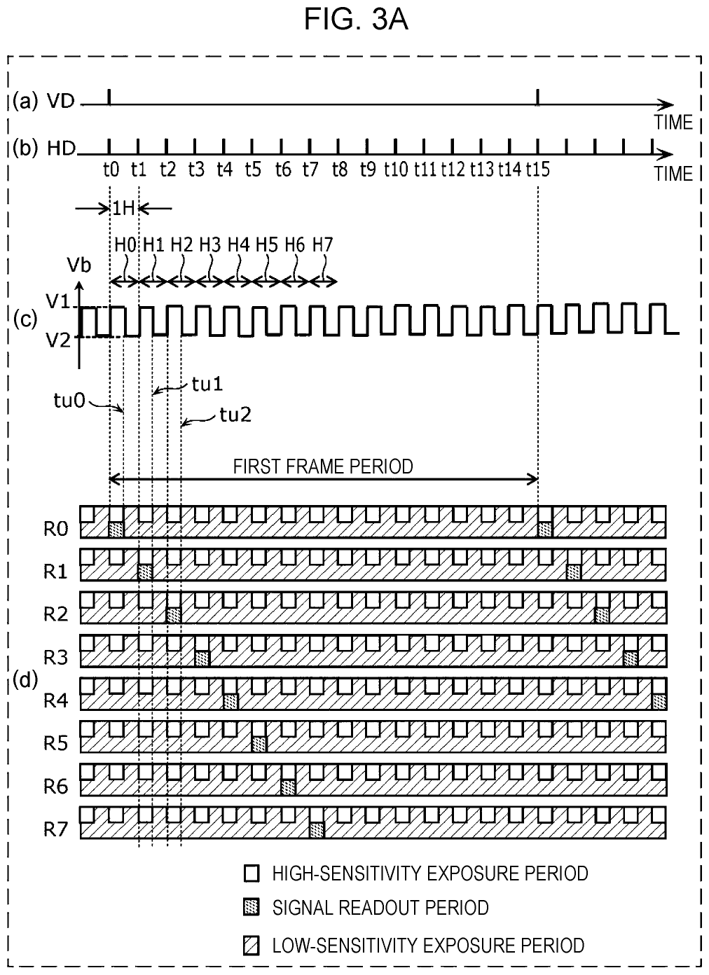

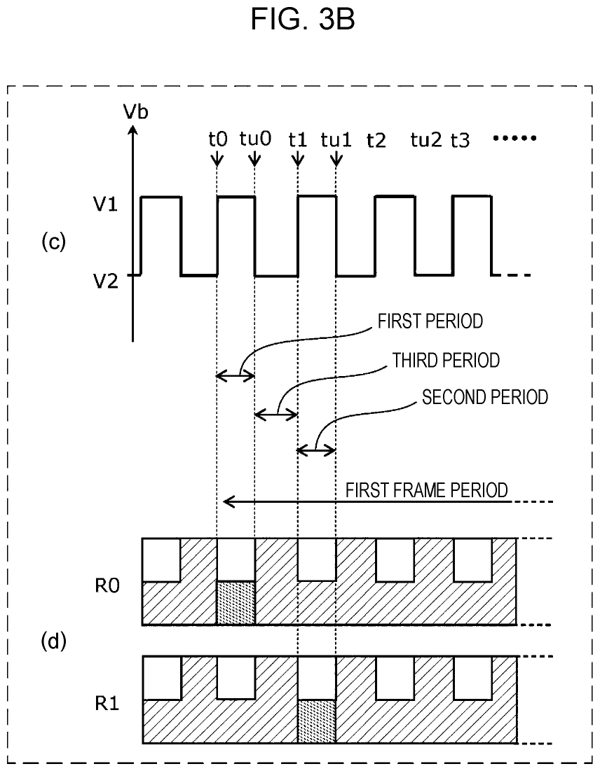

Referring to FIGS. 3A and 3B, image acquisition using the high-sensitivity exposure period and the low-sensitivity exposure period will be described. FIG. 3A is a timing chart illustrating an example of the operation of the imaging device 100 according to the embodiment. FIG. 3B is an enlarged diagram of part of FIG. 3A. In FIG. 3A, a chart (a) illustrates timings of fall (or rise) of a vertical synchronization signal VD. A chart (b) illustrates timings of fall (or rise) of a horizontal synchronization signal HD. A chart (c) illustrates an example of temporal changes of a voltage Vb to be applied from the voltage supply circuit 32 to the counter electrode 12 through the sensitivity control line 42. A chart (d) schematically illustrates high-sensitivity exposure periods and low-sensitivity exposure periods. In addition, the chart (d) schematically illustrates signal readout periods in the respective rows of the pixel array PA. The reference of the voltage Vb is, for example, a ground potential of the imaging device 100. Although not illustrated in FIGS. 3A and 3B, a predetermined voltage Vs is applied from the voltage supply circuit 35 to the shield electrode 17 through the sensitivity control line 45. The voltage Vs is, for example, 0 V.

In the chart (d) in FIG. 3A, white rectangles in the upper half of the bar in each row schematically represent high-sensitivity exposure periods. Diagonally hatched parts in the upper half of the bar in each row schematically represent low-sensitivity exposure periods. Dot-hatched rectangles in the lower half of the bar in each row schematically represent signal readout periods in each row.

Now, an example of the operation of the imaging device 100 will be described. For simplicity, an operation example in which the number of rows of pixels included in the pixel array PA is eight in total, from Row R0 to Row R7, will be described below.

To acquire an image, in each of the unit pixels 10 in the pixel array PA, the charge accumulation section 41 is reset, and a pixel signal accumulated therein after reset is read out. In the imaging device 100 according to this embodiment, in one readout period, the pixel signal is read out, and the charge accumulation section 41 is reset in order to accumulate charge for the next frame period. For example, as illustrated in FIG. 3A, on the basis of the vertical synchronization signal VD, signal readout starts for a plurality of pixels that belong to Row R0. Time t0 is one of the start times.

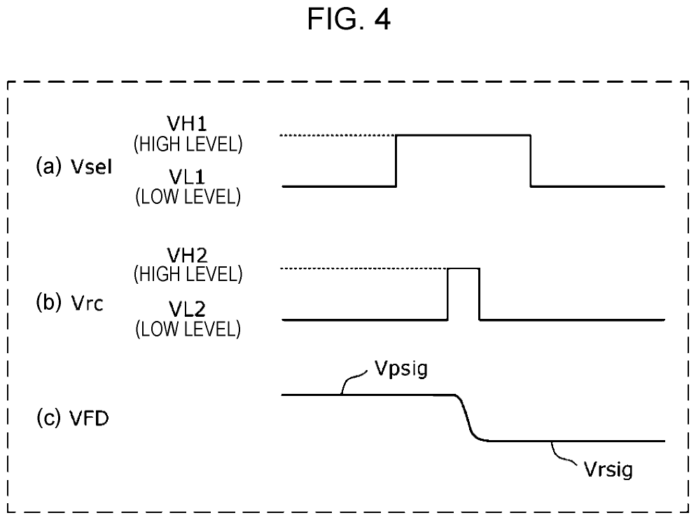

As described above, the period represented by each dot-hatched rectangle in the chart (d) in FIG. 3A is a signal readout period. FIG. 4 illustrates an example of timings chart of control signals in the signal readout period of the imaging device 100 according to the embodiment. In FIG. 4, “Vsel” in a chart (a) represents the potential of the address control line 46. The potential Vsel may change between VL1 being a low level and VH1 being a high level. “Vrc” in a chart (b) represents the potential of the reset control line 48. The potential Vrc may change between VL2 being a low level and VH2 being a high level. “VFD” in a chart (c) represents the potential of the charge accumulation section 41. The potential VFD at the time when the signal charge generated in an exposure period is accumulated in the charge accumulation section 41 is read out as a pixel signal Vpsig. The potential VFD immediately after the charge accumulation section 41 is reset is read out as a reset signal Vrsig.

At time t0 illustrated in FIGS. 3A and 3B, the signal readout period starts. In the signal readout period, first, on the basis of the vertical synchronization signal VD, the potential Vsel of the address control line 46 in Row R0 is switched from the low level to the high level. Thus, each address transistor 26 having the gate connected to the address control line 46 is turned on from the off state. Thus, the potential VFD of the charge accumulation section 41 is output to the corresponding vertical signal line 47. Specifically, the pixel signal Vpsig is output to the vertical signal line 47. The pixel signal Vpsig is a signal corresponding to the amount of charge accumulated in the charge accumulation section 41 at and after the last reset. The pixel signal Vpsig is transmitted to a column signal processing circuit 37.

Subsequently, the pixels that belong to Row R0 are reset. Between the readout of the pixel signal Vpsig and the reset, AD conversion of the pixel signal Vpsig may be performed in the column signal processing circuit 37.

The pixels that belong to Row R0 are reset as follows. As illustrated in FIG. 4, the potential Vrc of the reset control line 48 in Row R0 is switched from the low level to the high level. Thus, each reset transistor 28 having the gate connected to the reset control line 48 is turned on from the off state. Thus, the charge accumulation section 41 and the reset voltage line 44 are connected to each other, and the reset voltage Vr is supplied to the charge accumulation section 41. Thus, the potential of the charge accumulation section 41 is reset to the reset voltage Vr. The reset voltage Vr herein is, for example, 0 V.

Subsequently, the potential Vrc of the reset control line 48 is switched from the high level to the low level. Thus, the reset transistor 28 is turned off from the on state. After the reset transistor 28 is turned off, the reset signal Vrsig is read out from each of the unit pixels 10 in Row R0 through the corresponding vertical signal line 47. The reset signal Vrsig is a signal corresponding to the value of the reset voltage Vr. The reset signal Vrsig is transmitted to the column signal processing circuit 37.

After the reset signal Vrsig is read out, the potential Vsel of the address control line 46 is switched from the high level to the low level. Thus, the address transistor 26 is turned off from the on state.

As described above, the pixel signal Vpsig and the reset signal Vrsig that are read out are both transmitted to the column signal processing circuit 37. By obtaining the difference between these signals, a fixed pattern noise can be removed in the column signal processing circuit 37. Specifically, the reset signal Vrsig corresponds to a noise component, and by subtracting the noise component from the pixel signal Vpsig, the noise is removed.

In this example, as schematically illustrated in FIG. 3A, in accordance with the horizontal synchronization signal HD, signal readout and reset are sequentially performed on the pixels that belong to Row R0 to Row R7 in units of row. In the following description, an interval between pulses of the horizontal synchronization signal HD, in other words, a period from selection of a certain row until selection of the next row, may be referred to as “1H period”.

In this example, for example, a period H0 from time t0 to time t1 corresponds to a 1H period. A period H1 from time t1 to time t2 also corresponds to a 1H period. A period H2 from time t2 to time t3 also corresponds to a 1H period. A period H3 from time t3 to time t4 also corresponds to a 1H period. A period H4 from time t4 to time t5 also corresponds to a 1H period. A period H5 from time t5 to time t6 also corresponds to a 1H period. A period H6 from time t6 to time t7 also corresponds to a 1H period. A period H7 from time t7 to time t8 also corresponds to a 1H period.

In the period H0, signals are read out from the pixels that belong to Row R0. In the period H1, signals are read out from the pixels that belong to Row R1. In the period H2, signals are read out from the pixels that belong to Row R2. In the period H3, signals are read out from the pixels that belong to Row R3. In the period H4, signals are read out from the pixels that belong to Row R4. In the period H5, signals are read out from the pixels that belong to Row R5. In the period H6, signals are read out from the pixels that belong to Row R6. In the period H7, signals are read out from the pixels that belong to Row R7. In the example in FIG. 3A, readout from the pixels that belong to each row is performed in the high-sensitivity exposure period. Note that in the example illustrated herein, signals are read out from the pixels in one row in each high-sensitivity exposure period. However, signals may be sequentially read out from the pixels in a plurality of rows in each high-sensitivity exposure period. In the exposure control examples according to this embodiment to be described later, signals are sequentially read out from the pixels in a plurality of rows in each low-sensitivity exposure period or each high-sensitivity exposure period.

In this embodiment, the 1H periods included in a first frame have an equal length. However, these lengths may be different from each other.

In the example in FIG. 3A, on the basis of the vertical synchronization signal VD, scanning is performed on the eight rows from Row R0 to Row R7. The scanning herein is signal readout from the pixels that belong to each row.

While signals are read out from the pixels in the period H0, the period H1, the period H2, the period H3, the period H4, the period H5, the period H6, and the period H7, a voltage V1 is applied from the voltage supply circuit 32 to the counter electrode 12.

Specifically, at time t0, the voltage Vb applied from the voltage supply circuit 32 to the counter electrode 12 is switched from a voltage V2 to the voltage V1. Subsequently, at time tu0, the voltage Vb is switched from the voltage V1 to the voltage V2. Subsequently, at time t1, the voltage Vb is switched from the voltage V2 to the voltage V1. Subsequently, at time tu1, the voltage Vb is switched from the voltage V1 to the voltage V2. Subsequently, at time t2, the voltage Vb is switched from the voltage V2 to the voltage V1. Subsequently, at time tu2, the voltage Vb is switched from the voltage V1 to the voltage V2. In subsequent steps, switching of the voltage Vb is repeated in such a manner.

The voltage V2 is typically a voltage with which the potential difference between the pixel electrode 11 and the counter electrode 12 becomes less than or equal to 0 V. This potential difference will be further described below. As described above, by turning on the reset transistor 28, the reset voltage Vr can be supplied from the reset voltage source 34 to the charge accumulation section 41 through the reset voltage line 44 and the reset transistor 28. By the reset voltage Vr being supplied to the charge accumulation section 41, the voltage of the pixel electrode 11 is also reset to the reset voltage Vr. By setting the voltage V2 to be equal to the reset voltage Vr, the above potential difference can be made 0 V when the voltage of the pixel electrode 11 is reset to the reset voltage Vr. As described above, the reset voltage Vr may be 0 V.

In a state where the bias voltage applied to the photoelectric conversion layer 15 is 0 V, most of charge generated in the photoelectric conversion layer 15 is eliminated. This is assumed to be because most of positive and negative charge generated by light irradiation may immediately be eliminated due to recombination. On the other hand, signal charge accumulated in the charge accumulation section 41 in the high-sensitivity exposure period is not eliminated and is held until a reset operation of the pixel is performed. The signal charge is not discarded by switching between the low-sensitivity exposure state and the high-sensitivity exposure state. As a result, even if the high-sensitivity exposure period and the low-sensitivity exposure period are repeated, the signal charge accumulated in respective high-sensitivity exposure periods is integrated. In the high-sensitivity exposure periods, in the above example, the bias voltage is 10 V. Note that when a positive bias voltage is applied to the photoelectric conversion layer 15 in low-sensitivity exposure periods, signal charge is accumulated also in the low-sensitivity exposure periods. In such a case, signal charge accumulated in the low-sensitivity exposure periods in addition to in the high-sensitivity exposure periods is integrated.

### EXPOSURE CONTROL EXAMPLES

Next, exposure control examples using the imaging device 100 in a case of imaging a subject whose luminance changes cyclically, for example, an LED that blinks in a fixed cycle, will be described. Note that each of the exposure control examples using the imaging device 100 is also an imaging method performed by the imaging device 100.

### Reference Example

Prior to description of the exposure control examples using the imaging device 100 according to this embodiment, first, an exposure control example using a typical imaging device will be described as a reference example.

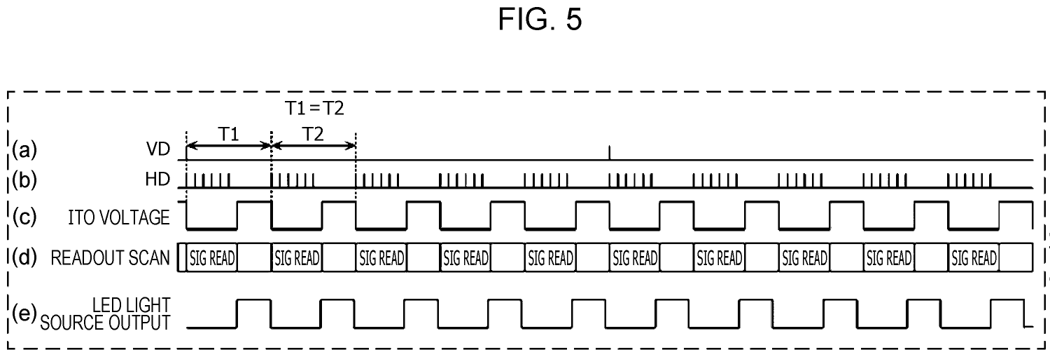

FIG. 5 is a timing chart illustrating the exposure control example using the imaging device according to the reference example. In this example, exposure control timings for two frames are illustrated. “VD” in a chart (a) illustrates a vertical synchronization signal. “HD” in a chart (b) illustrates a horizontal synchronization signal. “ITO voltage” in a chart (c) illustrates temporal changes of a voltage to be applied to a counter electrode in a photoelectric converter. “Readout scan” in a chart (d) illustrates signal readout periods in which signal readout and reset are sequentially performed for pixels in one or more rows in the pixel array PA. Sections denoted by “SIG READ” is the signal readout periods. “LED light source output” in a chart (e) illustrates a blinking state of the LED that is the subject. The high level corresponds to the on state, whereas the low level corresponds to the off state.

In FIG. 5, the cycle of the bias voltage to be applied to the photoelectric converter is fixed. In addition, the cycle of the bias voltage to be applied to the photoelectric converter slightly differs from the cycle in which the LED blinks. That is, the cycle of the ITO voltage in the chart (c) slightly differs from the cycle in which the LED light source blinks in the chart (e). Here, “cycle of the bias voltage” is the total length of the successive low-sensitivity exposure period and high-sensitivity exposure period and is also referred to as exposure cycle. The cycle of the bias voltage means each of T1 and T2 in FIG. 5, for example. Note that in the cycle of the bias voltage, the order of the low-sensitivity exposure period and the high-sensitivity exposure period may be reversed. That is, the cycle of the bias voltage may be the total length of the successive high-sensitivity exposure period and low-sensitivity exposure period.

In the exposure control example illustrated in FIG. 5, the length of a period in which the high-sensitivity exposure period and an LED-on period, in which the LED is in the on state, overlap each other gradually changes over time. Furthermore, this change is repeated cyclically over a plurality of frames. In a frame in which the period in which the high-sensitivity exposure period and the LED-on period overlap each other is long, the luminance of the subject increases. On the other hand, in a frame in which the period in which the high-sensitivity exposure period and the LED-on period overlap each other is short, the luminance of the subject decreases. Since the length of the period in which the high-sensitivity exposure period and the LED-on period overlap each other changes cyclically, the frame in which the luminance of the subject is high and the frame in which the luminance of the subject is low are repeated cyclically. Flicker occurs in this manner.

In the imaging device 100 according to this embodiment, the occurrence of flicker is reduced by any of exposure controls described in the following first to sixth exposure control examples.

### First Exposure Control Example

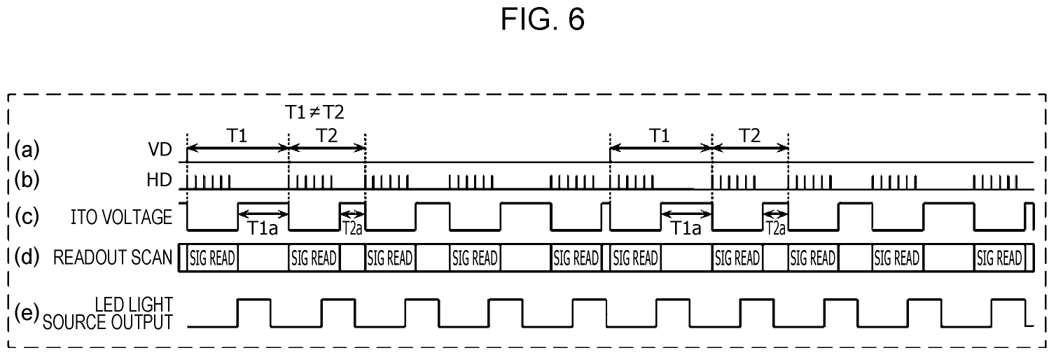

FIG. 6 is a timing chart illustrating the first exposure control example using the imaging device 100 according to the embodiment. Here, exposure control timings for two frames are illustrated. Charts (a) to (e) correspond to those in FIG. 5. In this exposure control example, the cycle of the bias voltage to be applied to the photoelectric converter 13 is not fixed in one frame. For example, T1 differs from T2 in FIG. 6. In this exposure control example, the exposure cycle is changed in one frame. This can reduce the phenomenon in which the length of the period in which the high-sensitivity exposure period and the LED-on period overlap each other changes cyclically. This can suppress the phenomenon in which the frame in which the luminance of the subject is high and the frame in which the luminance of the subject is low are repeated cyclically, that is, flicker.

Note that in FIG. 6, T1a indicates the high-sensitivity exposure period in a bias voltage cycle T1, whereas T2a indicates the high-sensitivity exposure period in a bias voltage cycle T2. In this exposure control example, the bias voltage cycle T1 differs from the bias voltage cycle T2, and in addition, the high-sensitivity exposure period T1a in the bias voltage cycle T1 also differs from the high-sensitivity exposure period T2a in the bias voltage cycle T2.

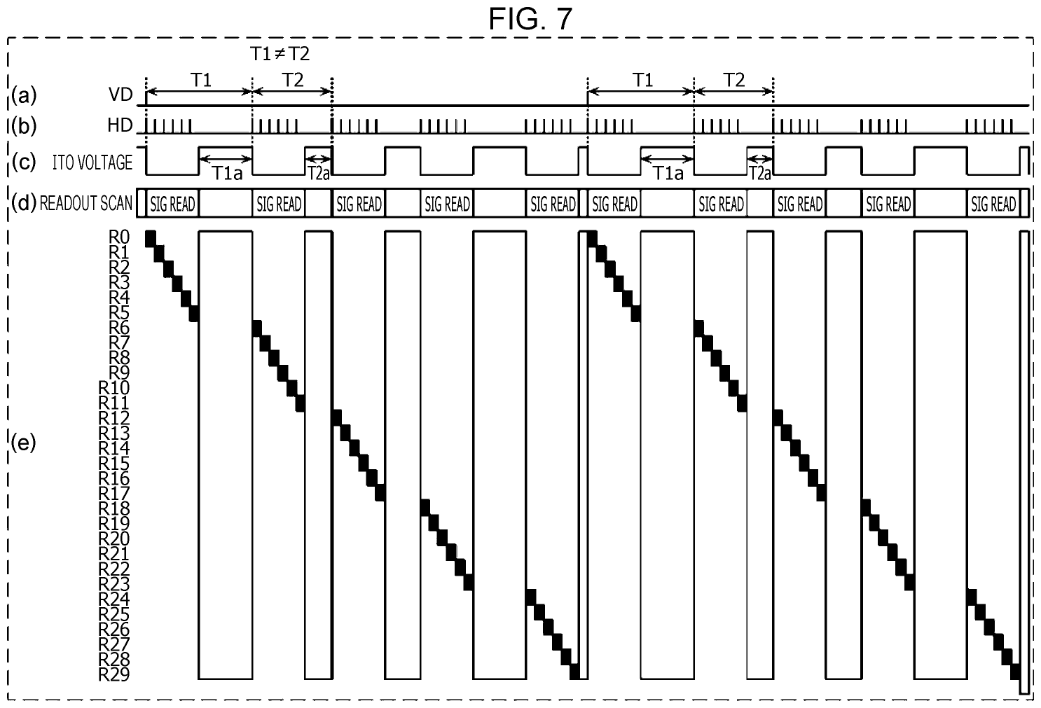

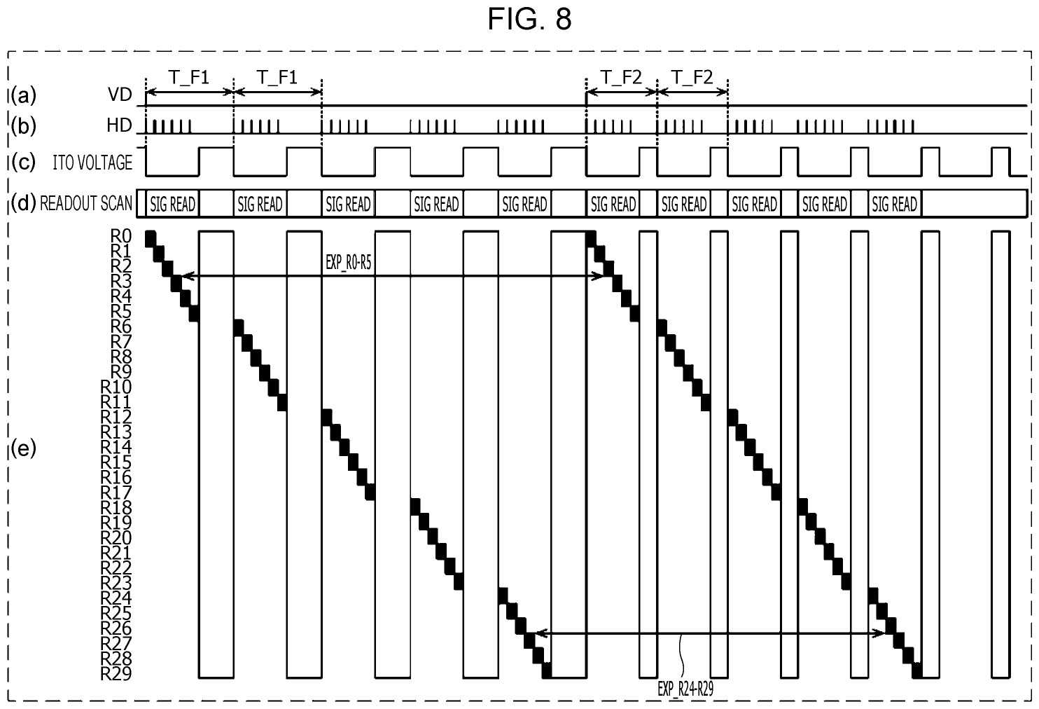

FIG. 7 is a detailed timing chart illustrating the first exposure control example using the imaging device 100 according to the embodiment. In FIG. 7, the chart (e) in FIG. 6 is replaced with a diagram schematically illustrating signal readout periods in the respective rows in the pixel array PA. Charts (a) to (d) correspond to those in FIG. 6. A chart (e) illustrates the chart (d) in more detail. Note that in the following FIGS. 8 to 12, charts (a) to (e) correspond to those in FIG. 7.

In the chart (e), the signal readout periods in the respective rows in the pixel array PA from Row R0 to Row R29 are illustrated. The signal readout periods in the respective rows are represented by black squares. Signal readout and reset are sequentially performed on Row R0 to Row R5 in the low-sensitivity exposure period, and subsequently, high-sensitivity exposure is performed for six HD ranges. Subsequently, signal readout and reset are sequentially performed on Row R6 to Row R11 in the low-sensitivity exposure period, and subsequently, high-sensitivity exposure is performed for three HD ranges. In this manner, by differing the length of the high-sensitivity exposure period after the signal readout scanning, the exposure frequency is dispersed. Thus, the occurrence of flicker is suppressed. Note that dispersion of the exposure frequency can also be said as dispersion of the exposure cycle.

In the above manner, in this exposure control example, the voltage supply circuit 32 alternately supplies a first voltage and a second voltage to the photoelectric converter 13 in a first frame period so as to form a first low-sensitivity exposure period, a first high-sensitivity exposure period, a second low-sensitivity exposure period, and a second high-sensitivity exposure period successively in this order, and the total length of the first low-sensitivity exposure period and the first high-sensitivity exposure period (“T1” in FIGS. 6 and 7) differs from the total length of the second low-sensitivity exposure period and the second high-sensitivity exposure period (“T2” in FIGS. 6 and 7). Thus, since the total length of the successive low-sensitivity exposure period and high-sensitivity exposure period varies in one frame period, it is possible to obtain an image in which the occurrence of flicker is reduced even under a light source that blinks with a specific frequency.

In addition, in this exposure control example, the length of the first high-sensitivity exposure period (“T1a” in FIGS. 6 and 7) differs from the length of the second high-sensitivity exposure period (“T2a” in FIGS. 6 and 7). In this manner, by changing the lengths of the high-sensitivity exposure periods in the frame, the exposure cycle may be changed. Furthermore, by making the lengths of the low-sensitivity exposure periods fixed in the frame, signal readout may be performed for pixels in the same number of rows in each of the low-sensitivity exposure periods. In addition, in this exposure control example, the imaging device 100 includes the signal detection transistor 24 including a gate connected to the photoelectric converter 13, and the signal detection transistor 24 outputs a signal corresponding to a potential of the gate in a period in which the first voltage is supplied to the photoelectric converter 13. Thus, the signal is read out in the low-sensitivity exposure period.

Although this exposure control example employs a rolling shutter in which exposure is performed on every six rows in the pixel array PA at the same time, the number of rows is not limited to this number, and the method is not limited to the rolling shutter. For example, the present disclosure is also applicable to a global shutter sensor in which exposure is performed on all the rows in the pixel array PA at the same time.

In addition, strictly speaking, although a rise/fall edge of “ITO voltage” and the timing of a row signal readout period (black square in the drawing) do not overlap each other in this exposure control example, they may overlap each other. In the imaging device 100 according to this embodiment, exposure and signal readout are independent of each other, and may or may not be performed simultaneously.

In addition, whether LED flicker has occurred may be determined, for example, on the basis of whether an average of output of a region designated in a screen varies in different frames. In addition, the determination result may be fed back to the cycle of the bias voltage to be applied to the photoelectric converter. That is, by changing the cycle of the bias voltage to be applied to the photoelectric converter in a frame depending on the determination result, flicker may be suppressed.

### Second Exposure Control Example

FIG. 8 is a detailed timing chart illustrating the second exposure control example using the imaging device 100 according to the embodiment. Here, exposure control timings including row scanning for two frames are illustrated. In this exposure control example, although the cycle of the bias voltage is kept fixed in a frame, the cycle of the bias voltage is changed in different frames. Here, bias voltage cycles “T_F2” in a second frame are shorter than bias voltage cycles “T_F1” in a first frame.

In the imaging device according to the reference example, since the cycle of the bias voltage is fixed in a frame, if a light source emits light with a specific frequency, suppression of the occurrence of flicker may fail in some cases. However, when the occurrence of flicker is detected, by changing the exposure cycle in the next frame to an exposure cycle with which the exposure frequency is comparatively largely separated from the frequency of the light source as in this exposure control example, the occurrence of flicker can be suppressed.

In addition, in this exposure control example, the length of the high-sensitivity exposure period differs in different frames. Thus, the length differs for each of the total of high-sensitivity exposure periods for Row R0 to Row R5 (i.e., the total of high-sensitivity exposure periods in EXP_R0-R5 in the drawing), the total of high-sensitivity exposure periods for Row R6 to Row R11, the total of high-sensitivity exposure periods for Row R12 to Row R17, the total of high-sensitivity exposure periods for Row R18 to Row R23, and the total of high-sensitivity exposure periods for Row R24 to Row R29 (i.e., the total of high-sensitivity exposure periods in EXP_R24-R29 in the drawing). Accordingly, by changing the gain when amplifying the signal read out from each row, output values in the entire frame may be made uniform. Alternatively, the frame in which the exposure frequency is switched may be masked as an invalid frame. That is, an image may refrain from being output in a frame in a switching period until the total of the high-sensitivity exposure periods in the rows becomes equal after the exposure frequency is switched.

In the above manner, in this exposure control example, the voltage supply circuit 32 alternately supplies a first voltage and a second voltage to the photoelectric converter 13 in a first frame period so as to form a first low-sensitivity exposure period and a first high-sensitivity exposure period successively in this order, and alternately supplies the first voltage and the second voltage to the photoelectric converter 13 in a second frame period, which is different from the first frame period, so as to form a second low-sensitivity exposure period and a second high-sensitivity exposure period successively in this order, and the total length of the first low-sensitivity exposure period and the first high-sensitivity exposure period (“T_F1”) differs from the total length of the second low-sensitivity exposure period and the second high-sensitivity exposure period (“T_F2”). Thus, by changing the total length of the low-sensitivity exposure period and the high-sensitivity exposure period in different frames, it is possible to obtain an image in which the occurrence of flicker is reduced even under a light source that blinks with a specific frequency.

In addition, in this exposure control example, the length of the first high-sensitivity exposure period differs from the length of the second high-sensitivity exposure period. In this manner, by changing the lengths of the high-sensitivity exposure periods in different frames, the exposure cycle may be changed. Furthermore, by making the lengths of the low-sensitivity exposure periods fixed in different frames, signal readout may be performed for pixels in the same number of rows in each of the low-sensitivity exposure periods.

### Third Exposure Control Example

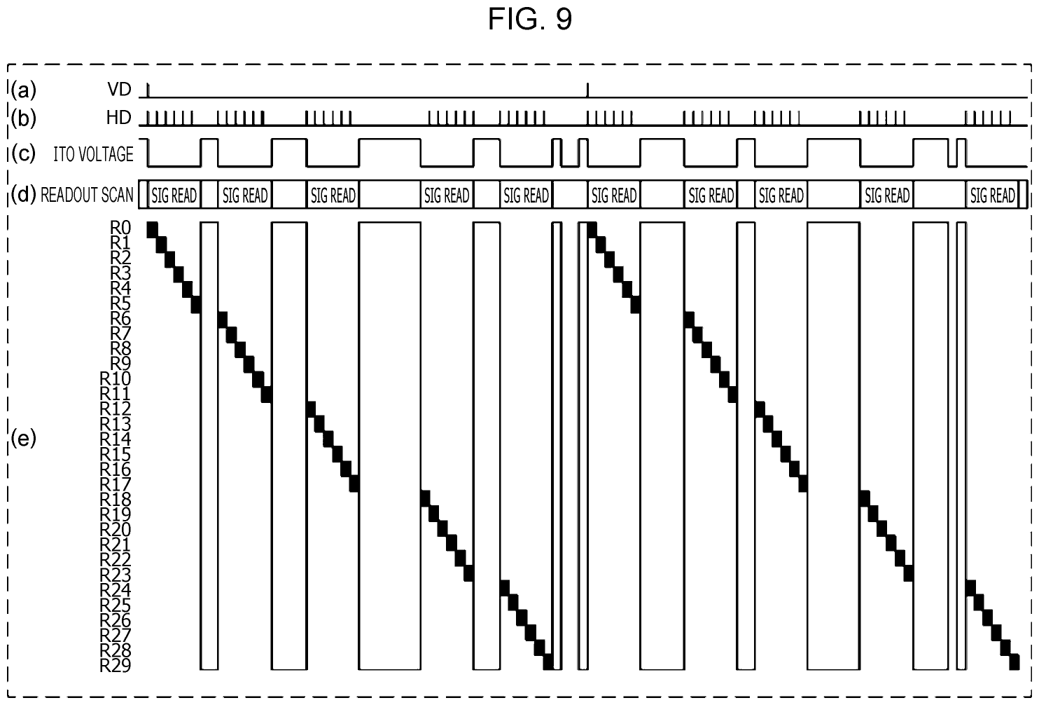

FIG. 9 is a detailed timing chart illustrating the third exposure control example using the imaging device 100 according to the embodiment. Here, exposure control timings including row scanning for two frames are illustrated. In this exposure control example, the lengths of high-sensitivity exposure periods are changed in a frame and in different frames. Note that the lengths of low-sensitivity exposure periods are fixed in a frame and in different frames.

Also with such exposure control, since the total length of the successive low-sensitivity exposure period and high-sensitivity exposure period is changed in a frame and in different frames, it is possible to obtain an image in which the occurrence of flicker is reduced even under a light source that blinks with a specific frequency.

Also in this case, as in the second exposure control example, the length differs for each of the total of high-sensitivity exposure periods for Row R0 to Row R5, the total of high-sensitivity exposure periods for Row R6 to Row R11, the total of high-sensitivity exposure periods for Row R12 to Row R17, the total of high-sensitivity exposure periods for Row R18 to Row R23, and the total of high-sensitivity exposure periods for Row R24 to Row R29. Accordingly, by changing the gain when amplifying the signal read out from each row, output values in the entire frame may be made uniform.

### Fourth Exposure Control Example

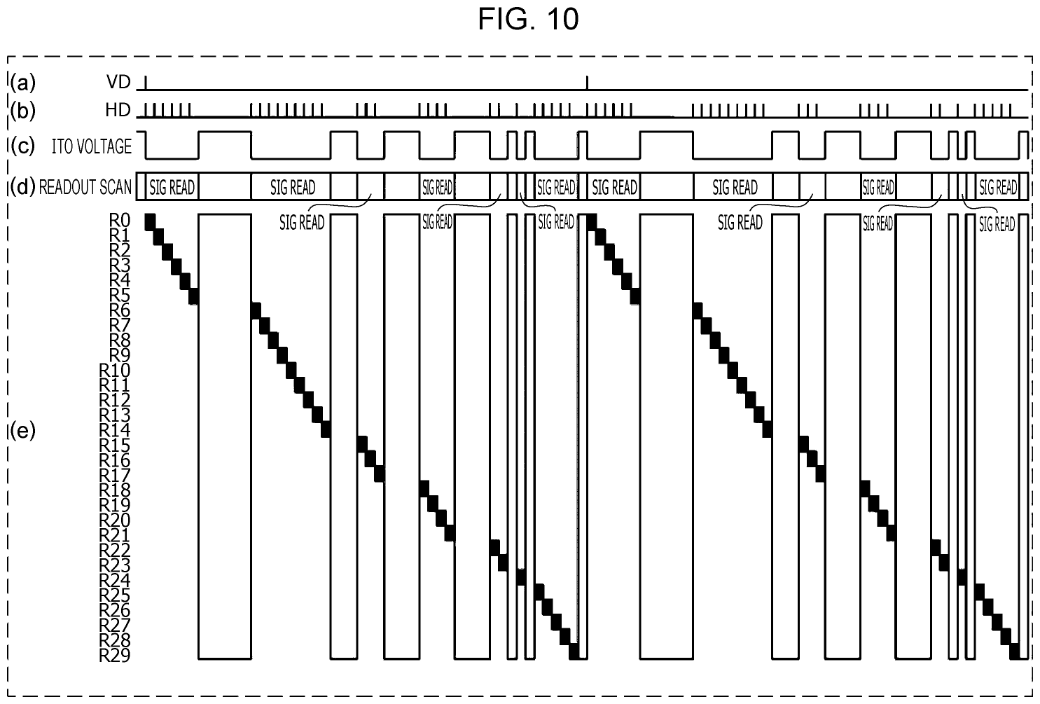

FIG. 10 is a detailed timing chart illustrating the fourth exposure control example using the imaging device 100 according to the embodiment. Here, exposure control timings including row scanning for two frames are illustrated. In this exposure control example, by changing both the lengths of low-sensitivity exposure periods and the lengths of high-sensitivity exposure periods in a frame, the exposure frequency (or the exposure cycle) is changed in the frame. In addition, the number of rows on which signal readout is performed in each of the low-sensitivity exposure periods is increased or decreased in accordance with the length of the low-sensitivity exposure period. Note that the same exposure control is repeated in different frames.

Also with such exposure control, since the total length of the successive low-sensitivity exposure period and high-sensitivity exposure period is changed in a frame, it is possible to obtain an image in which the occurrence of flicker is reduced even under a light source that blinks with a specific frequency.

### Fifth Exposure Control Example

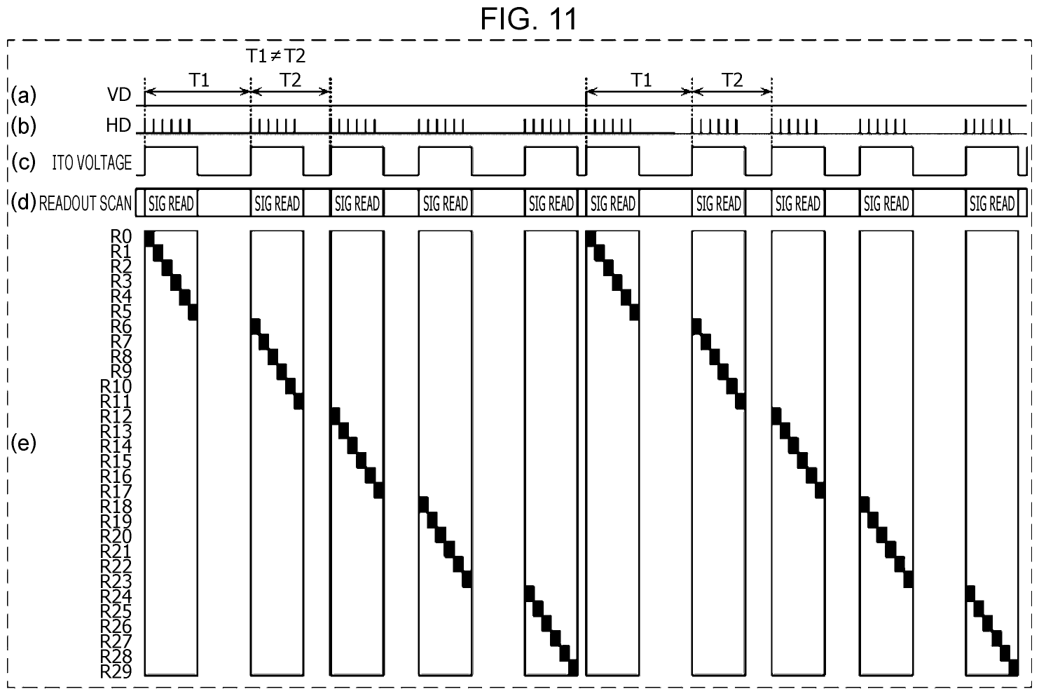

FIG. 11 is a detailed timing chart illustrating the fifth exposure control example using the imaging device 100 according to the embodiment. Here, exposure control timings including row scanning for two frames are illustrated. In this exposure control example, by changing the lengths of low-sensitivity exposure periods, the exposure frequency (or the exposure cycle) is changed in a frame. In addition, in this exposure control example, signal readout is performed in high-sensitivity exposure periods. Note that the same exposure control is repeated in different frames.

In the above manner, the voltage supply circuit 32 alternately supplies a first voltage and a second voltage to the photoelectric converter 13 in a first frame period so as to form a first low-sensitivity exposure period, a first high-sensitivity exposure period, a second low-sensitivity exposure period, and a second high-sensitivity exposure period successively in this order, and the total length of the first low-sensitivity exposure period and the first high-sensitivity exposure period (“T1” in FIG. 11) differs from the total length of the second low-sensitivity exposure period and the second high-sensitivity exposure period (“T2” in FIG. 11). Thus, since the total length of the successive low-sensitivity exposure period and high-sensitivity exposure period varies in one frame period, it is possible to obtain an image in which the occurrence of flicker is reduced even under a light source that blinks with a specific frequency. In addition, in this exposure control example, the two low-sensitivity exposure periods have different lengths. That is, the length of the first low-sensitivity exposure period differs from the length of the second low-sensitivity exposure period. In this manner, by changing the lengths of the low-sensitivity exposure periods in a frame, the exposure cycle may be changed. Furthermore, by making the lengths of the high-sensitivity exposure periods fixed in a frame, signal readout may be performed on the same number of rows in each of the high-sensitivity exposure periods.

In addition, in this exposure control example, the imaging device 100 includes the signal detection transistor 24 including a gate connected to the photoelectric converter 13, and the signal detection transistor 24 outputs a signal corresponding to a potential of the gate in a period in which the second voltage is supplied to the photoelectric converter 13. Thus, the signal is read out in the high-sensitivity exposure period.

### Sixth Exposure Control Example

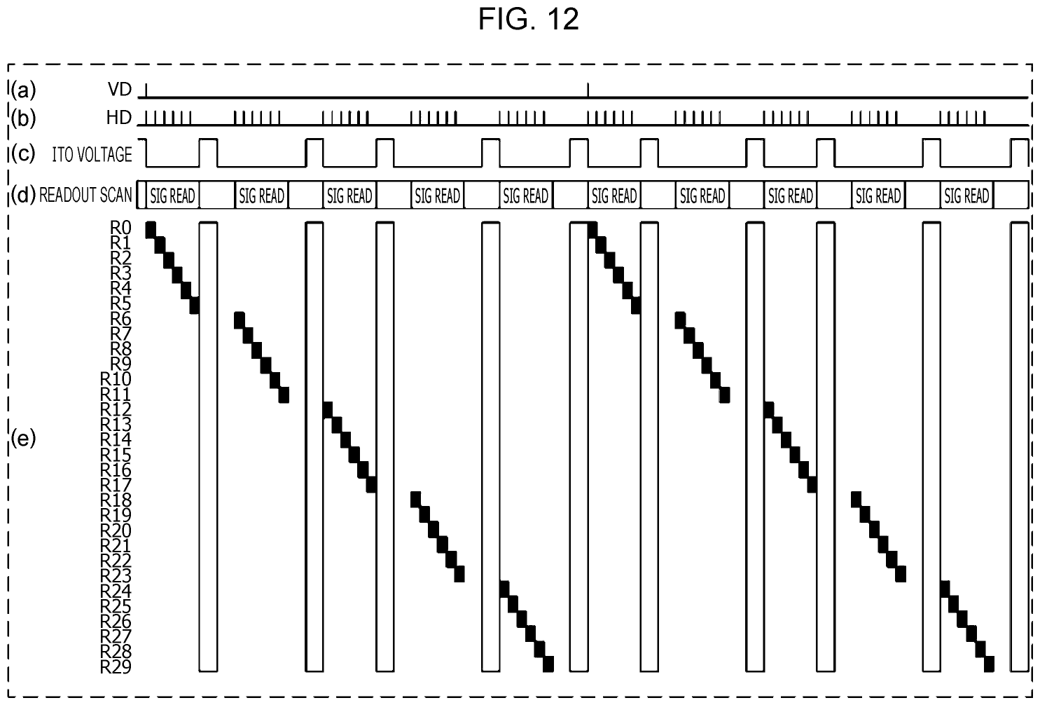

FIG. 12 is a detailed timing chart illustrating the sixth exposure control example using the imaging device 100 according to the embodiment. Here, exposure control timings including row scanning for two frames are illustrated. In this exposure control example, by making the lengths of the high-sensitivity exposure periods fixed and changing the lengths of the low-sensitivity exposure periods, the exposure frequency (or the exposure cycle) is changed in a frame. In addition, in this exposure control example, signal readout is performed cyclically on the same number of rows in each of the low-sensitivity exposure periods. Note that the same exposure control is repeated in different frames.

Also with such exposure control, since the exposure timing is changed in a frame, it is possible to obtain an image in which the occurrence of flicker is reduced even under a light source that blinks with a specific frequency.

In addition, in this exposure control example, the photoelectric converter 13 is one of a plurality of photoelectric converters arranged in a matrix, a plurality of signal detection transistors 24 corresponding to the plurality of photoelectric converters 13 sequentially output, in units of row, signals corresponding to a plurality of rows in respective periods, each of the signals being a signal corresponding to a potential of a gate of a corresponding one of the plurality of signal detection transistors 24, each of the periods being a period in which the first voltage or the second voltage is supplied to a corresponding one of the photoelectric converters 13, and the plurality of signal detection transistors 24 cyclically output the signals corresponding to the plurality of rows. Thus, readout of the signals from the photoelectric converters 13 in a fixed number of rows is repeated in a fixed cycle.

The imaging device and the imaging method according to aspects of the present disclosure have been described above on the basis of the embodiment and the plurality of exposure control examples. However, the present disclosure is not limited to the embodiment and the plurality of exposure control examples. The scope of the present disclosure also includes various modifications conceived by those skilled in the art that are made to the embodiment and the plurality of exposure control examples and combinations of some of structural elements or timings in the embodiment and the plurality of exposure control examples without departing from the spirit of the present disclosure.

For example, exposure control may be performed by combining all or some of the first to sixth exposure control examples as appropriate.

In addition, all or part of exposure controls illustrated in the first to sixth exposure control examples may be implemented in the imaging device 100. In a case where a plurality of exposure controls are implemented in the imaging device 100, from among these exposure controls, one selected by a user instruction or setting may be performed.

The imaging device according to the embodiment of the present disclosure is applicable to various camera systems and sensor systems by which an image in which the occurrence of flicker is reduced can be obtained even under a light source that blinks with a specific frequency, such as a digital still camera, a medical camera, a surveillance camera, an in-vehicle camera, a digital single-lens reflex camera, and a digital mirrorless single-lens camera.

What is claimed is:

1. An imaging device comprising:
a photoelectric converter whose sensitivity changes depending on a value of a voltage to be applied; and
a voltage supply circuit that alternately supplies a first voltage and a second voltage, which is different from the first voltage, to the photoelectric converter, wherein
in a first frame period, a length of a first period from a first point in time at which the first voltage is switched to the second voltage until a second point in time at which the first voltage is switched to the second voltage subsequently to the first point in time differs from a length of a second period from the second point in time until a third point in time at which the first voltage is switched to the second voltage subsequently to the second point in time.

2. An imaging device comprising:
a photoelectric converter whose sensitivity changes depending on a value of a voltage to be applied; and
a voltage supply circuit that alternately supplies a first voltage and a second voltage, which is different from the first voltage, to the photoelectric converter, wherein
in each of a first frame period and a second frame period, which is different from the first frame period, the voltage supply circuit cyclically supplies the first voltage and the second voltage, and
a cycle of a voltage change in the first frame period differs from a cycle of a voltage change in the second frame period.

3. The imaging device according to claim 1, wherein a length of a third period from the first point in time until a fourth point in time at which the second voltage is switched to the first voltage subsequently to the first point in time differs from a length of a fourth period from the second point in time until a fifth point in time at which the second voltage is switched to the first voltage subsequently to the second point in time.

4. The imaging device according to claim 1, wherein a length of a fifth period from a fourth point in time at which the second voltage is switched to the first voltage subsequently to the first point in time until the second point in time differs from a length of a sixth period from a fifth point in time at which the second voltage is switched to the first voltage subsequently to the second point in time until the third point in time.

5. The imaging device according to claim 1, wherein the sensitivity of the photoelectric converter when the first voltage is applied is higher than the sensitivity of the photoelectric converter when the second voltage is applied.

6. The imaging device according to claim 1, wherein the sensitivity of the photoelectric converter when the first voltage is applied is lower than the sensitivity of the photoelectric converter when the second voltage is applied.

7. The imaging device according to claim 1, further comprising a signal detection transistor including a gate connected to the photoelectric converter, wherein
the signal detection transistor outputs a signal corresponding to a potential of the gate in a period in which the first voltage is supplied to the photoelectric converter.

8. The imaging device according to claim 1, further comprising a signal detection transistor including a gate connected to the photoelectric converter, wherein
the signal detection transistor outputs a signal corresponding to a potential of the gate in a period in which the second voltage is supplied to the photoelectric converter.

9. The imaging device according to claim 7, wherein the photoelectric converter is one of a plurality of photoelectric converters arranged in a matrix,
a plurality of signal detection transistors corresponding to the plurality of photoelectric converters sequentially output, in units of row, signals corresponding to a plurality of rows in respective periods, each of the signals being a signal corresponding to a potential of a gate of a corresponding one of the plurality of signal detection transistors, each of the periods being a period in which the first voltage is supplied to a corresponding one of the plurality of photoelectric converters, and
the plurality of signal detection transistors cyclically output the signals corresponding to the plurality of rows.

10. The imaging device according to claim 1, wherein the photoelectric converter includes a first electrode, a second electrode, and a photoelectric conversion layer sandwiched between the first electrode and the second electrode, and
the voltage supply circuit alternately supplies the first voltage and the second voltage to the first electrode of the photoelectric converter.

11. The imaging device according to claim 2, wherein the photoelectric converter includes a first electrode, a second electrode, and a photoelectric conversion layer sandwiched between the first electrode and the second electrode, and
the voltage supply circuit alternately supplies the first voltage and the second voltage to the first electrode of the photoelectric converter.

12. An imaging method using a photoelectric converter whose sensitivity changes depending on a value of a voltage to be applied, the imaging method comprising:
alternately supplying a first voltage and a second voltage, which is different from the first voltage, to the photoelectric converter, wherein
in a first frame period, a length of a first period from a first point in time at which the first voltage is switched to the second voltage until a second point in time at which the first voltage is switched to the second voltage subsequently to the first point in time differs from a length of a second period from the second point in time until a third point in time at which the first voltage is switched to the second voltage subsequently to the second point in time.

13. An imaging method using a photoelectric converter whose sensitivity changes depending on a value of a voltage to be applied, the imaging method comprising:
in each of a first frame period and a second frame period, which is different from the first frame period, cyclically supplying a first voltage and a second voltage to the photoelectric converter, wherein
a cycle of a voltage change in the first frame period differs from a cycle of a voltage change in the second frame period.
